(19) United States
(12) Patent Application Publication
(10) Pub. No.: US 2021/0165294 A1
(43) Pub. Date: Jun. 3, 2021

(54) ARRAY SUBSTRATE AND DRIVING METHOD THEREOF, MANUFACTURING METHOD AND DISPLAY APPARATUS

(71) Applicants: BOE TECHNOLOGY GROUP CO., LTD., Beijing (CN); Hefei Xinsheng Optoelectronics Technology Co., Ltd., Hefei, Anhui (CN)

(72) Inventors: Xuebing Jiang, Beijing (CN); Jilei Gao, Beijing (CN)

(21) Appl. No.: 15/775,263

(22) PCT Filed: Aug. 24, 2017
(86) PCT No.: PCT/CN2017/098836

§ 371 Date: May 10, 2018

(30) Foreign Application Priority Data
Jan. 16, 2017 (CN) 201710030511.1

(51) Int. Cl. G02F 1/1362; G02F 1/1368; H01L 27/12; G09G 3/36

(52) U.S. Cl. CPC G02F 1/136295; G02F 1/1368; G09G 2300/0809; H01L 27/1259; G09G 3/3648; H01L 27/124

(57) ABSTRACT

The embodiments of the present disclosure provide an array substrate, a driving method of an array substrate, a manufacturing method of an array substrate, and a display apparatus. The array substrate comprises a plurality of pixel units, each of which comprises a thin film transistor and a pixel electrode, wherein the thin film transistor comprises a gate line, a source connected to the pixel electrode, and a drain, wherein the gate line has a first overlapped region with the source in an orthogonal projection direction perpendicular to the array substrate, and each pixel unit further comprises an additional signal line provided to have a second overlapped region with the source in the orthogonal projection direction.

### CROSS-REFERENCE TO RELATED APPLICATION(S)

This application is a Section 371 National Stage Application of International Application No. PCT/CN2017/098836, filed on Aug. 24, 2017, entitled “ARRAY SUBSTRATE AND DRIVING METHOD THEREOF, MANUFACTURING METHOD AND DISPLAY APPARATUS,” which claims priority to the Chinese Patent Application No. 201710030511.1, filed on Jan. 16, 2017, incorporated herein by reference in their entirety.

### TECHNICAL FIELD

The embodiments of the present disclosure relate to an array substrate, a driving method thereof, a manufacturing method thereof, and a display apparatus.

### BACKGROUND

A thin film transistor-based Liquid Crystal Display (LCD) includes a plurality of pixel units. Each of the pixel units comprises a pixel electrode and a thin film transistor, wherein the thin film transistor acts as a driving element of the pixel unit. In such a pixel structure, a gate voltage V_{g} change from a turn-on voltage to a turn-off voltage causes a jump of a pixel voltage Vₚ, wherein a jump voltage is ΔVₚ. The existence of a jump voltage ΔVₚ causes poor display, such as flicker and mura of grayscales of a picture on a display screen of a display apparatus. In a conventional array substrate, the jump voltage ΔVₚ is reduced by, for example, reducing a gate-source overlapped area of the thin film transistor and increasing a thickness of a gate insulating layer. However, the conventional technical solution may cause problems such as breakoff of a source line and increased difficulty in manufacturing the array substrate.

### SUMMARY

At least one embodiment of the present disclosure provides an array substrate, a driving method of an array substrate, a manufacturing method of an array substrate, and a display apparatus to overcome or alleviate the above technical problems.

According to an aspect of the present disclosure, there is proposed an array substrate comprising a plurality of pixel units, each of which comprises a thin film transistor and a pixel electrode, wherein the thin film transistor comprises a gate line, a source connected to the pixel electrode, and a drain,

wherein the gate line has a first overlapped region with the source in an orthogonal projection direction perpendicular to the array substrate, and each pixel unit further comprises an additional signal line provided to have a second overlapped region with the source in the orthogonal projection direction.

In an example, the additional signal line may be substantially parallel to an extension direction of the gate line, and a distance between the additional signal line and the gate line is equal to or greater than 5 μm.

In an example, the first overlapped region may have an area equal to an area of the second overlapped region.

In an example, a length of the second overlapped region in an extension direction of the source may be in a range of 18 μm to 25 μm.

In an example, the additional signal line may be provided in the same layer as the gate line.

In an example, the additional signal line may be provided in the same layer as the pixel electrode.

According to another aspect of the present disclosure, there is further provided a display apparatus comprising the array substrate according to the embodiments of the present disclosure.

According to another aspect of the present disclosure, there is further provided a driving method of the array substrate according to the embodiments of the present disclosure, comprising:

changing a voltage applied to the additional signal line from a third voltage to a fourth voltage when a voltage applied to the gate line is changed from a first voltage to a second voltage, wherein a difference between the first voltage and the second voltage is opposite in sign to a difference between the third voltage and the forth voltage.

In an example, an absolute value of the difference between the first voltage and the second voltage may be equal to an absolute value of the difference between the third voltage and the fourth voltage.

According to another aspect of the present disclosure, there is further provided a manufacturing method of an array substrate, which may comprise:

forming a common electrode layer;

forming a gate line and a gate insulation layer;

forming an active layer, a source, and a drain; and

forming a pixel electrode,

wherein the manufacturing method further comprises forming an additional signal line.

In an example, the additional signal line may be formed to be located in the same layer as the gate line.

In an example, the additional signal line may be formed to be located in the same layer as the pixel electrode.

In an example, the additional signal line may be formed to be substantially parallel to an extension direction of the gate line, and a distance between the additional signal line and the gate line is equal to or greater than 5 μm.

In an example, the additional signal line may be formed to have an overlapped region with the source, and a length of the overlapped region in an extension direction of the source is in a range of 18 μm to 25 μm.

According to the embodiments of the present disclosure, the additional signal line is provided so that the additional signal line has an overlapped region with the source in the orthogonal projection direction perpendicular to the array substrate, so as to form an additional capacitance Cₐₛ between the additional signal line and the source. The voltage on the additional signal line is set so that when the voltage applied to the gate line suddenly changes, the voltage applied to the additional signal line changes in an opposite direction. This sudden change in the voltage on the additional signal line may be coupled to the source by the capacitance Cₐₛ, thereby compensating for the jump voltage ΔVₚ caused by the sudden change in the voltage on the gate line.

### BRIEF DESCRIPTION OF THE DRAWINGS

In order to more clearly describe the technical solutions according to the embodiments of the present disclosure or in the conventional technologies, the accompanying drawings needed to be used in the description of the embodiments will be briefly described below. Obviously, the accompanying drawings in the following description are only some embodiments of the present disclosure. For those of ordinary skill in the art, other accompanying drawings can also be obtained based on these accompanying drawings without any creative work, wherein:

FIG. 1 illustrates a structural diagram of an exemplary pixel unit in an array substrate;

FIG. 2A illustrates a sectional view taken along a cutting line A-A′ in FIG. 1;

FIG. 2B illustrates an enlarged schematic view of a region A1 in FIG. 1;

FIG. 3A illustrates an equivalent capacitance diagram of the pixel unit in FIG. 1, and FIG. 3B illustrates an exemplary waveform diagram of a gate voltage, a pixel voltage, and a jump voltage in the circuit of FIG. 3A;

FIG. 4 illustrates an equivalent capacitance diagram of a pixel unit according to an embodiment of the present disclosure;

FIG. 5 illustrates a structural diagram of an array substrate according to a first embodiment of the present disclosure;

FIG. 6A illustrates a sectional view taken along a cutting line B-B′ in FIG. 5;

FIG. 6B illustrates an enlarged schematic view of a region A5 in FIG. 5;

FIG. 7 illustrates a structural diagram of an array substrate according to a second embodiment of the present disclosure;

FIG. 8A illustrates a sectional view taken along a cutting line C-C′ in FIG. 7;

FIG. 8B illustrates an enlarged schematic view of a region A7 in FIG. 7;

FIG. 9 illustrates a schematic flowchart of a driving method of an array substrate according to an embodiment of the present disclosure;

FIG. 10 illustrates a signal timing diagram of a driving method of an array substrate according to an embodiment of the present disclosure;

FIG. 11 illustrates a schematic flowchart of a manufacturing method of an array substrate according to the first embodiment of the present disclosure; and

FIG. 12 illustrates a schematic flowchart of a manufacturing method of an array substrate according to the second embodiment of the present disclosure.

### DETAILED DESCRIPTION

In order to make the purposes, technical solutions and advantages of the embodiments of the present disclosure more clear, the technical solutions in the embodiments of the present disclosure will be clearly and completely described below in conjunction with the accompanying drawings in the embodiments of the present disclosure. Obviously, the embodiments described are a part of the embodiments of the present disclosure instead of all the embodiments. All other embodiments obtained by those of ordinary skill in the art based on the described embodiments of the present disclosure without contributing any creative work are within the protection scope of the present disclosure. It should be noted that throughout the accompanying drawings, the same elements are represented by the same or similar reference signs. In the following description, some specific embodiments are for illustrative purposes only and are not to be construed as limiting the present disclosure, but merely examples of the embodiments of the present disclosure. The conventional structure or construction will be omitted when it may cause confusion with the understanding of the present disclosure. It should be noted that shapes and dimensions of components in the figures do not reflect true sizes and proportions, but only illustrate contents of the embodiments of the present disclosure.

Unless otherwise defined, technical terms or scientific terms used in the embodiments of the present disclosure should be of ordinary meanings to those skilled in the art. “First”, “second” and similar words used in the embodiments of the present disclosure do not represent any order, quantity or importance, but are merely used to distinguish between different constituent parts.

In addition, it can be understood that when an element such as a layer, a film, a region or a substrate etc. is referred to as being located “on” or “below” another element, the element may be “directly” located “on” or “below” the other element, or there may also be an intermediate element therebetween. In addition, “on” or “below” only represents a relative positional relationship, and the “on” or “below” relationship may change accordingly when the element or the entire device is turned over. The present disclosure will be described herein using a relative positional relationship in which a substrate is used as an underlying layer.

In a TFT-based LCD display, a direction in which liquid crystal molecules are arranged changes under the action of an external electric field, so as to control the degree of light transmission through liquid crystal. Currently, common TFT-LCD display modes mainly comprise a vertical alignment mode, a twisted nematic mode, a planar field mode, etc. An Advanced super Dimension Switch (ADS)-type liquid crystal display controls the arrangement of liquid crystal in a liquid crystal cell by generating a planar fringe electric field between a top-layer comb electrode (a pixel electrode) and an underlying planar electrode (a common electrode) on a substrate of a TFT. For the convenience of description, the following description will be made using the ADS-type liquid crystal display. It can be understood by those skilled in the art that main features of the ADS-type liquid crystal display lie in a direction of an electric field and positioning of the pixel electrode on an upper layer of the common electrode, and a structure of the TFT device as a driving element is basically the same. Therefore, the following description is equally applicable to other types of array substrates.

It should be understood that a source and a drain of the thin film transistor used are symmetrical, and therefore the source and the drain are interchangeable. In addition, for the convenience of description, the present disclosure will be described hereinafter by taking an NPN-type transistor as an example. That is, a turn-on voltage of the thin film transistor below is at a high level, and a turn-off voltage of the thin film transistor is at a low level.

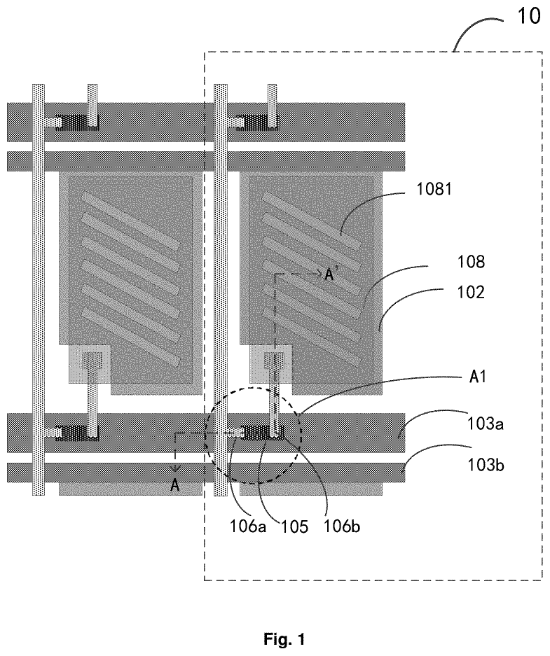

FIG. 1 illustrates a structural diagram of an exemplary pixel unit in an array substrate, wherein a pixel unit 10 is denoted by a dashed box. As shown in FIG. 1, the pixel unit 10 may comprise a common electrode layer 102, a gate line 103a, a common electrode line 103b, an active layer 105, a drain 106a of a thin film transistor, a source 106b of the thin film transistor, and a pixel electrode layer 108. In FIG. 1, A1 represents a region of a TFT device. In an example of FIG. 1, the pixel electrode layer 108 comprises a strip-shaped pixel electrode 1081.

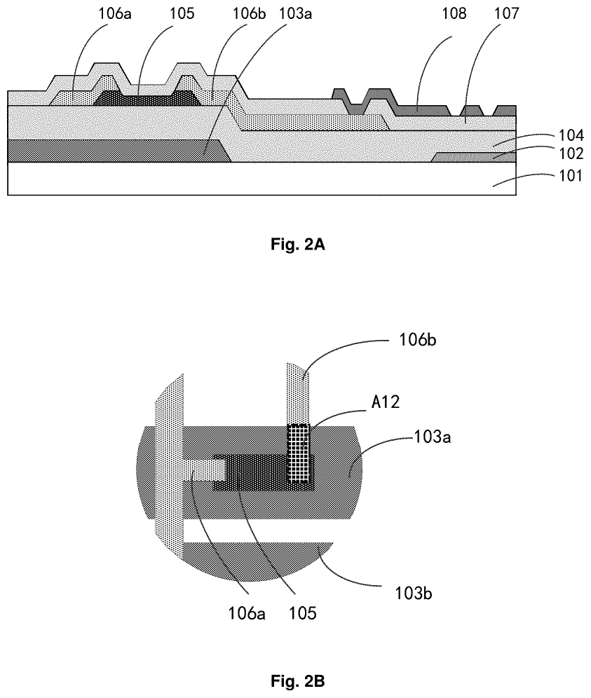

FIG. 2A illustrates a sectional view taken along a cutting line A-A′ in FIG. 1. As shown in FIG. 2A, the pixel unit 10 may comprise a substrate 101, the common electrode layer 102, the gate line 103a, the common electrode line 103b, a gate insulating layer 104, the drain 106a, the source 106b, a passivation layer 107, and the pixel electrode layer 108. The substrate 101 may be, for example, a glass substrate.

FIG. 2B illustrates an enlarged schematic view of a region A1 in FIG. 1. As shown in FIG. 2B, the region A1 further comprises a region A12. A12 is a region where the source 106b overlaps with the gate line 103a in an orthogonal projection direction. It should be noted that a direction perpendicular to the substrate 101 is defined herein as the “orthogonal projection direction.”

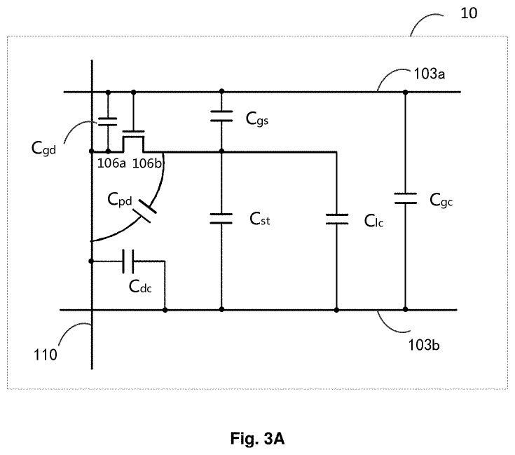

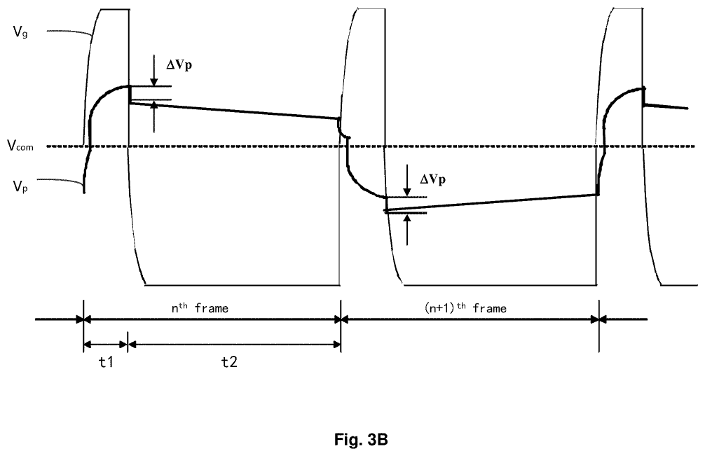

FIG. 3A illustrates an equivalent capacitance diagram of the pixel unit 10 in FIG. 1. As shown in the figure, in the exemplary pixel unit 10, a portion of the gate line 103a in the region A1 constitutes a gate of the TFT, the drain 106a is connected to the data line 110, and the source 106b is connected to the common electrode line 103b. The drain 106a and the source 106b are in the same layer and are adjacent to the pixel electrode layer 108, and the pixel electrode layer 108 is located in an upper layer of the common electrode layer 102. As shown in FIG. 3A, a capacitance C_{gd} represents a capacitance between the gate line 103a and the drain 106a and may comprise C_{gd_on} (a charged body is the gate insulating layer 104) and C_{gd_off} (a charged body is the gate insulating layer 104 and the active layer 105.) C_{gs} represents a capacitance between the gate line 103a and the source 106b and may comprise C_{gs} on (a charged body is the gate insulating layer 104) and C_{gs} off (a charged body is the gate insulating layer 104 and the active layer 105.) C_{gc} represents a capacitance between the gate line 103a and the common electrode line 103b, and a charged body is the gate insulating layer 104 and the passivation layer 107. Cₛₜ represents a capacitance between the pixel electrode 1081 and the common electrode line 103b, and a charged body is the passivation layer 107. C_{ic} represents a capacitance between the pixel electrode 1081 and the common electrode line 103b, a charged body is liquid crystal molecules, and C_{ic} is a coupling capacitance and needs to be obtained by simulation. C_{dr} represents a capacitance between the data line 110 and the common electrode line 103b, and a charged body is the passivation layer 107. C_{pd} represents a coupling capacitance between the pixel electrode 1081 and the data line 110. Among the above capacitances, Cₛₜ and C_{ic} are effective capacitances for controlling deflection of the liquid crystal, and the remaining capacitances are all parasitic capacitances, wherein C_{ic} is a fringe field capacitance for controlling the deflection of the liquid crystal, and provides a voltage for the deflection of the liquid crystal.

An important factor in determining the quality of switching of the TFT is the parasitic capacitance C_{gs} between a gate metal and a source metal. As the switching of the TFT is close to be in a transient state, when the gate voltage V_{g} instantly decreases from a turn-on voltage V_{gh} of the TFT to a turn-off voltage V_{gi} of the TFT, a change amount ΔV_{g} of V_{g} is coupled to the pixel electrode by the parasitic capacitance C_{gs} of the TFT, which causes the pixel voltage Vₚ to jump with a jump amount of ΔVₚ, which is called a jump voltage. Due to the presence of the jump voltage ΔVₚ, the pixel voltage becomes (Vₚ−ΔVₚ).

FIG. 3B illustrates an exemplary waveform diagram of the gate voltage V_{g}, the pixel voltage Vₚ, and the jump voltage ΔVₚ in the circuit of FIG. 3A. As shown in FIG. 3B, by taking an n^{th} frame image as an example, a display phase of the image may comprise a charging phase which is denoted as t1; and a voltage holding phase which is denoted as t2. In t1, the gate voltage V_{g} rapidly increases to the turn-on voltage V_{gh} of the TFT, while the pixel voltage Vₚ gradually increases, and then the procedure proceeds to the voltage holding phase t2. In the voltage holding phase t2, the gate voltage V_{g} instantly decreases from the turn-on voltage V_{gh} to the turn-off voltage V_{gi} of the TFT, and a change amount ΔV_{g} of V_{g} is coupled to the pixel electrode 1081 by the parasitic capacitance C_{gs} of the TFT, which causes the pixel voltage Vₚ to jump with a jump voltage of ΔVₚ.

According to the principle of charge conservation, a theoretical formula of ΔVₚ can be obtained according to an equation (1) below.

$$Δ {V}_{p} = \frac{{C}_{g s}}{{C}_{g s} + {C}_{lc} + {C}_{s t}} Δ {V}_{g} \qquad ( 1 )$$

In order to suppress the jump voltage ΔVₚ, C_{gs} may be decreased.

According to an embodiment of the present disclosure, there is provided an array substrate. The array substrate comprises a plurality of pixel units, each of which comprises a thin film transistor and a pixel electrode, wherein the thin film transistor comprises a gate line, a source connected to the pixel electrode, and a drain, wherein the gate line has a first overlapped region with the source in an orthogonal projection direction, and each pixel unit further comprises an additional signal line provided to have a second overlapped region with the source in the orthogonal projection direction.

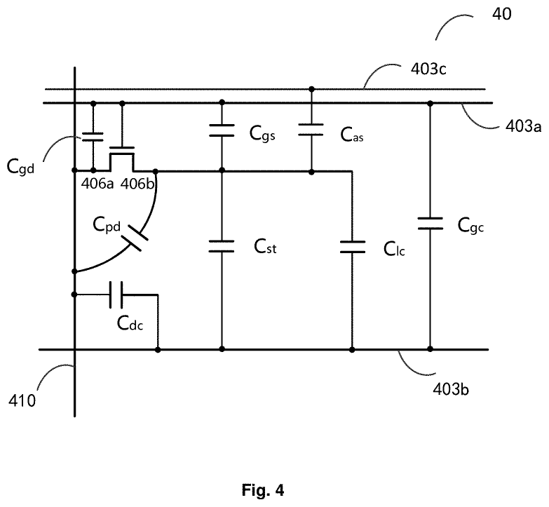

FIG. 4 illustrates an equivalent capacitance diagram of a pixel unit 40 according to an embodiment of the present disclosure. For brevity, in the following description, structures and/or functions in FIG. 4 which are the same as or similar to those illustrated in FIG. 3A will not be described again. As shown in FIG. 4, an additional signal line 403c is provided so that the additional signal line 403c has a second overlapped region with the source 403b in the orthogonal projection direction, to form an additional capacitance Cₐₛ between the additional signal line 403c and the source 403b. A voltage Vₐ applied to the additional signal line 403c is set, so that when the voltage applied to the gate line 403a suddenly changes from V_{gh} to V_{gl}, the voltage Vₐ applied to the additional signal line 403c changes in an opposite direction. This sudden change in the voltage on the additional signal line 403c will be coupled to the source 403b by the capacitance Cₐₛ, thereby compensating for the jump voltage ΔVₚ caused by the sudden change in the voltage on the gate line 403a.

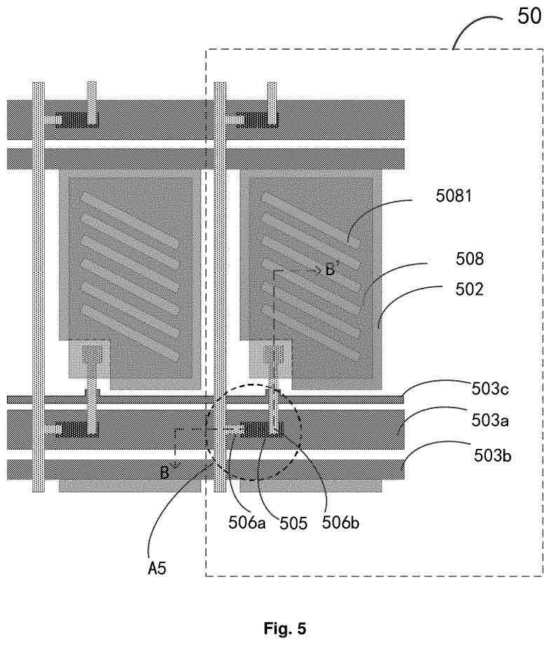

FIG. 5 illustrates a structural diagram of an array substrate according to a first embodiment of the present disclosure. As shown in FIG. 5, a thin film transistor of a pixel unit 50 comprises a gate line 503a, a drain 506a, and a source 506b, wherein the gate line 503a has a first overlapped region with the source 506b in an orthogonal projection direction. Each pixel unit 50 further comprises an additional signal line 503c which is provided to have a second overlapped region with the source 506b in the orthogonal projection direction.

In FIG. 5, the pixel unit 50 further comprises a common electrode layer 502, a common electrode line 503b, an active layer 505, and a pixel electrode layer 508. In FIG. 5, A5 represents a region of a TFT device. Similarly to the example of FIG. 1, the pixel electrode layer 508 comprises a strip-shaped pixel electrode 5081, and the source 506 is connected to the pixel electrode 5081. For brevity, in the following description, structures and/or functions which are the same as or similar to as those of the embodiment shown in FIG. 1 will not be described again.

As shown in FIG. 5, the common electrode layer 502 having a planar structure and the pixel electrode 5081 having a strip-shaped structure are two plates for driving deflection of liquid crystal, and are used to provide a common voltage V_{com} and a pixel voltage Vₚ for forming an electric field for the deflection of the liquid crystal respectively. The gate line 503a is used to provide a turn-on voltage V_{gh} and a turn-off voltage V_{gl} of the TFT. The gate insulating layer 504 and the active layer 505 are semiconductor layers. The drain 506a of the TFT and the source 506b of the TFT are connected to both terminals of the active layer 505 respectively. The source 506b of the TFT is electrically connected to the pixel electrode layer 108 via vias on the passivation layer 507.

When the turn-on voltage V_{gh} is applied to the gate line 503a, the active layer 505 is in a turn-on state, and a voltage of a signal on the data line is transferred to the pixel electrode 5081 via a path of the drain 506a→the active layer 505→the source 506b→the pixel electrode layer 508. When the turn-off voltage V_{gl} is applied to the gate line 503a, the active layer 505 is in a turn-off state, and only weak leakage current flows through the active layer 505 at this time.

In the first embodiment shown in FIG. 5, the additional signal line 503c is provided in the same layer as the gate line 503a. For example, the additional signal line 503c may be formed using metals such as copper and aluminum etc. Copper may be preferably used because of its high electrical conductivity. The gate line 503a and the additional signal line 503c may be patterned at one time using the same metal material as the gate line 503a, thereby simplifying the process flow. Although the additional signal line 503c is shown in FIG. 5 to be parallel to the gate line 503a and the common electrode line 503b, it can be understood by those skilled in the art that “parallel” here should be understood as that the additional signal line 503c does not intersect with both the gate line 503a and the common electrode line 503b. In addition, although the additional signal line 503c is shown in FIG. 5 to have an elongated shape, in a specific example, a shape of the additional signal line 503c may be designed according to an actual pixel structure, and the embodiments of the present disclosure are not limited thereto.

For example, a length of the additional signal line 503c may be set to be equal to or greater than a length of the gate line 503a. For example, a thickness of the additional signal line 503c may be set to be the same as the gate line 503a. A width of the additional signal line 503c may be determined according to factors such as a size, a pixel density PPI, power consumption, transmittance, etc. of the array substrate. The additional signal line 503c has a second overlapped region with the source 506b in the orthogonal projection direction, and a length of the second overlapped region in an extension direction of the source 506b may be set in a range of 18 μm to 25 μm and, for example, may be set to 20 μm.

In the first embodiment shown in FIG. 5, the additional signal line 503c is provided in the same layer as the gate line 503a, and therefore there may be lateral coupling therebetween. For this reason, a distance between the additional signal line 503c and the gate line 503a may be set to be equal to or greater than 5 μm.

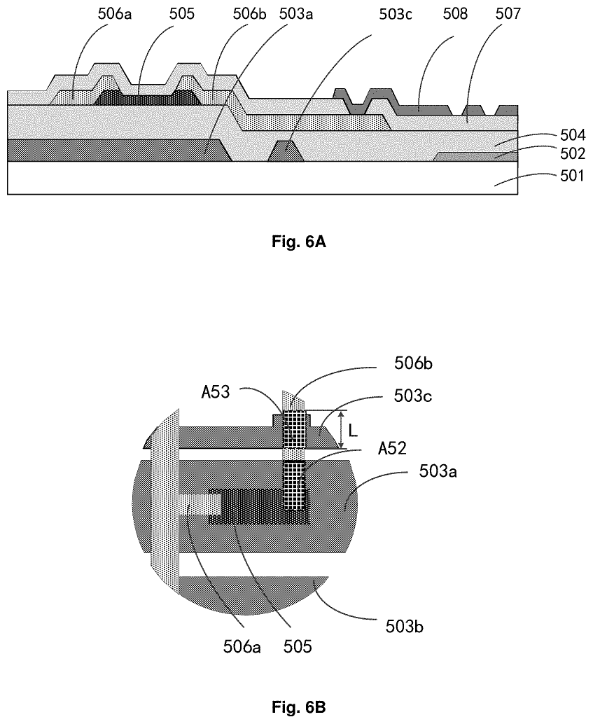

FIG. 6A illustrates a sectional view taken along a cutting line B-B′ in FIG. 5. As shown in FIG. 6A, the pixel unit 50 may comprise a substrate 501, a common electrode layer 502, a gate line 503a, a common electrode line 503b, an additional signal line 503c, a gate insulating layer 504, a drain 506a, a source 506b, a passivation layer 507, and a pixel electrode layer 508. The additional signal line 503c is provided in the same layer as the gate line 503a.

FIG. 6B illustrates an enlarged schematic view of a region A5 in FIG. 5. As shown in FIG. 6B, the region A5 further comprises a first overlapped region A52 and a second overlapped region A53. A52 is a region where the source 506b overlaps with the gate line 503a in an orthogonal projection direction, and A53 is a region where the source 506b overlaps the additional signal line 503c in the orthogonal projection direction. For example, an area of the first overlapped region A52 may be equal to an area of the second overlapped region A53. As shown in FIG. 6B, for example, a length L of the second overlapped region A53 in the extension direction of the source 506b may be set in a range of 18 μm to 25 μm and, for example, may be set to 20 μm.

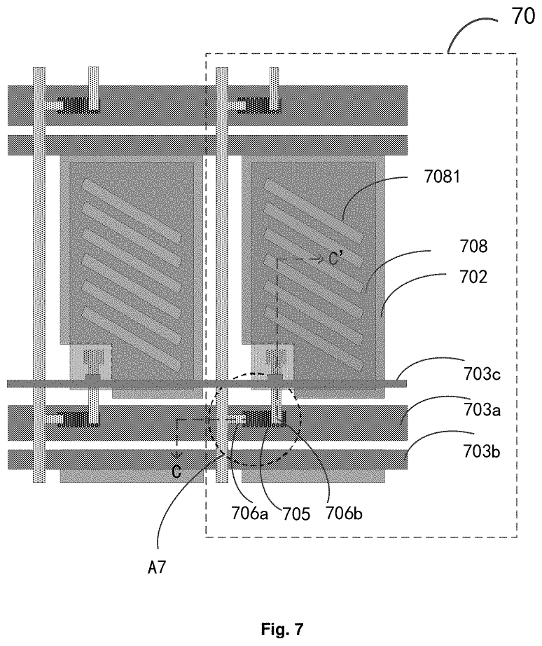

FIG. 7 illustrates a structural diagram of an array substrate according to a second embodiment of the present disclosure. As shown in FIG. 7, a thin film transistor of a pixel unit 70 comprises a gate line 703a, a drain 706a, and a source 706b, wherein the gate line 703a has a first overlapped region with the source 706b in an orthogonal projection direction. Each pixel unit 70 further comprises an additional signal line 703c which is provided to have a second overlapped region with the source 706b in the orthogonal projection direction.

In FIG. 7, the pixel unit 70 further comprises a common electrode layer 702, a common electrode line 703b, an active layer 705, and a pixel electrode layer 708. In FIG. 7, A7 represents a region of a TFT device. Similarly to the examples of FIGS. 1 and 5, the pixel electrode layer 708 comprises a strip-shaped pixel electrode 7081. For brevity, in the following description, structures and/or functions which are the same as or similar to those of the embodiments shown in FIGS. 1 and 5 will not be described again.

In the second embodiment shown in FIG. 7, the additional signal line 703c is provided in the same layer as the pixel electrode 7081, that is, in the pixel electrode layer 708. For example, the pixel electrode may be formed using a transparent conductive material, for example, including but not limited to indium zinc oxide, indium zinc oxide, indium tin oxide, indium tin oxide, etc. The pixel electrode and the additional signal line 703c may be patterned at one time using the same material as the pixel electrode, thereby simplifying the process flow. Although the additional signal line 703c is shown in FIG. 7 to be parallel to the gate line 703a and the common electrode line 703b, it can be understood by those skilled in the art that it only needs to have no overlapped region between the additional signal line 703c and both the gate line 703a and the common electrode line 703b in the orthogonal projection direction. In addition, although the additional signal line 703c is shown in FIG. 7 to have an elongated shape, in a specific example, a shape of the additional signal line 703c may be designed according to an actual pixel structure, and the embodiments of the present disclosure are not limited thereto.

A length of the additional signal line 703c may be set to be equal to or greater than a length of the gate line 703a. For example, a thickness of the additional signal line 703c may be set to be the same as the pixel electrode 7081. A width of the additional signal line 703c may be determined according to factors such as a size, a pixel density PPI, power consumption, transmittance etc. of the array substrate. The additional signal line 703c has a second overlapped region with the source 706b in the orthogonal projection direction, and a length of the second overlapped region in an extension direction of the source 706b may be set in a range of 18 μm to 25 μm and, for example, may be set to 20 μm.

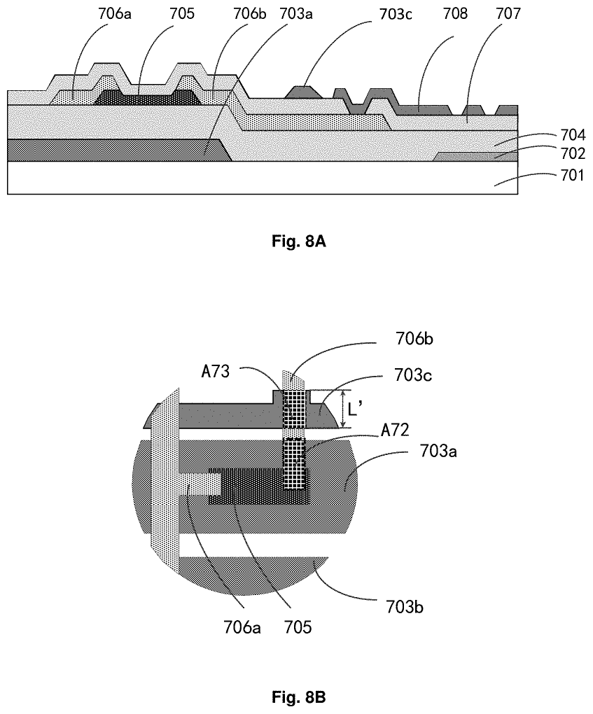

FIG. 8A illustrates a sectional view taken along a cutting line C-C′ in FIG. 7. As shown in FIG. 8A, the pixel unit 70 may comprise a substrate 701, a common electrode layer 702, a gate line 703a, a common electrode line 703b, an additional signal line 703c, a gate insulating layer 704, a drain 706a, a source 706b, a passivation layer 707, and a pixel electrode layer 708. The additional signal line 703c is provided in the same layer as the pixel electrode 7081.

FIG. 8B illustrates an enlarged schematic view of a region A7 in FIG. 7. As shown in FIG. 8B, the region A7 further comprises a first overlapped region A72 and a second overlapped region A73. A72 is a region where the source 706b overlaps with the gate line 703a in an orthogonal projection direction, and A73 is a region where the source 706b overlaps with the additional signal line 703c in the orthogonal projection direction. For example, an area of the first overlapped region A72 is equal to an area of the second overlapped region A73. As shown in FIG. 8B, for example, a length L′ of the second overlapped region A73 in the extension direction of the source 706b may be set in a range of 18 μm to 25 μm and, for example, may be set to 20 μm.

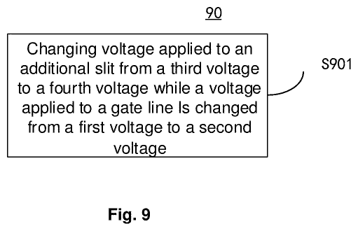

According to the embodiments of the present disclosure, there is also provided a driving method of an array substrate according to an embodiment of the present disclosure. FIG. 9 illustrates a flowchart of a driving method of an array substrate according to an embodiment of the present disclosure. It should be noted that serial numbers of various steps in the following method are merely used as a representation of the respective steps for the convenience of description, and should not be construed as indicating an execution order of the various steps. Unless explicitly stated, the method needs not to be performed exactly in the order shown. As shown in FIG. 9, the driving method 90 according to an embodiment of the present disclosure may comprise the following steps.

In step 901, a voltage applied to an additional signal line is changed from a third voltage to a fourth voltage while a voltage applied to a gate line is changed from a first voltage to a second voltage.

For example, a difference between the first voltage and the second voltage may be opposite to a difference between the third voltage and the fourth voltage in sign. In addition, an absolute value of the difference between the first voltage and the second voltage may be equal to an absolute value of the difference between the third voltage and the fourth voltage.

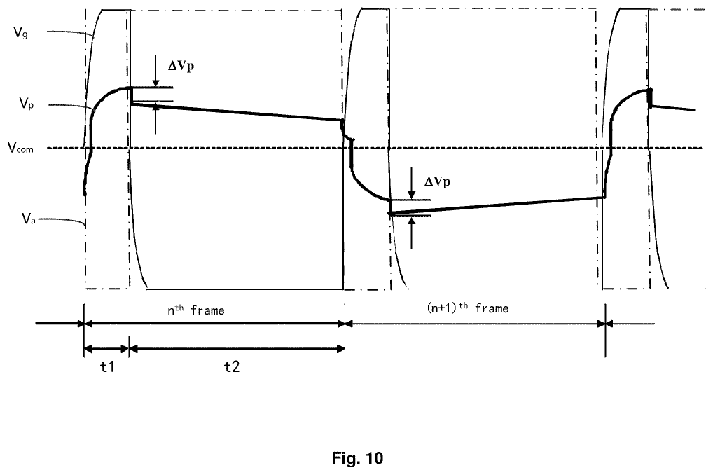

FIG. 10 illustrates a signal timing diagram of a driving method of an array substrate according to an embodiment of the present disclosure. In FIG. 10, for convenience of demonstration, a voltage V_{g} applied to a gate line is shown as a solid line, and a voltage Vₐ applied to an additional signal line is shown as a dashed-dotted line. As shown in FIG. 10, the voltage Vₐ applied to the additional signal line is changed from a third voltage to a fourth voltage while the voltage V_{g} applied to the gate line is changed from a first voltage (for example, a turn-on voltage V_{gh} of a gate) to a second voltage (for example, a turn-off voltage V_{gi} of the gate). A difference between the first voltage and the second voltage is opposite to a difference between the third voltage and the fourth voltage in sign. For example, if the voltage applied to the gate line is changed from the turn-on voltage V_{gh} of the gate to the turn-off voltage V_{gi} of the gate, the turn-on voltage V_{gh} of the gate is greater than the turn-off voltage V_{gi} of the gate, i.e., the difference between the first voltage and the second voltage is positive. In this case, when the gate voltage V_{g} is instantly changed from the turn-on voltage of the gate to the turn-off voltage of the gate, the voltage Vₐ is instantly changed from a third voltage Vₐ₁ to a fourth voltage Vₐ₂, wherein the third voltage Vₐ₁ is less than the fourth voltage Vₐ₂, that is, a difference between the third voltage and the fourth voltage is negative. Then, such a sudden change in the voltage on the additional signal line may be coupled to the source by the capacitance Cₐₛ, thereby compensating for a jump voltage ΔVₚ caused by the voltage V_{g} on the gate line.

In the array substrate according to an embodiment of the present disclosure, the gate voltage V_{g} may be directly applied to the additional signal line after being inverted. At this time, the third voltage has the same amplitude as the first voltage, and the fourth voltage has the same amplitude as the second voltage. The gate voltage V_{g} may also be inverted and amplified, and is then applied to the additional signal line. The voltage Vₐ may also be determined according to a ratio of an area of the first overlapped region between the source and the gate line in the orthogonal projection direction with relative to an area of the second overlapped region between the source and the additional signal line in the orthogonal projection direction. If the area of the second overlapped region is greater than the area of the first overlapped region, a coupling effect of the second overlapped region on the pixel voltage Vₚ is stronger, and amplitude of the voltage Vₐ may be set to be smaller, and vice versa. Generally, amplitude of the gate voltage V_{g} ranges from −10V to +30V, and the amplitude of the voltage Vₐ may be set correspondingly according to the amplitude of the gate voltage V_{g}.

The embodiments of the present disclosure further provide a manufacturing method of an array substrate. It should be noted that serial numbers of various steps in the following method are merely used as a representation of respective steps for the convenience of description, and should not be construed as indicating an execution order of the various steps. Unless explicitly stated, the method needs not to be performed exactly in the order shown. The manufacturing method of an array substrate according to an embodiment of the present disclosure may comprise forming a common electrode layer; forming a gate line and a gate insulating layer; forming an active layer, a source and a drain; and forming a pixel electrode.

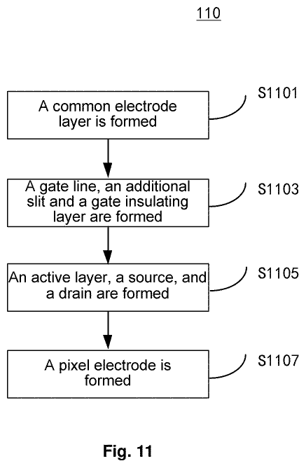

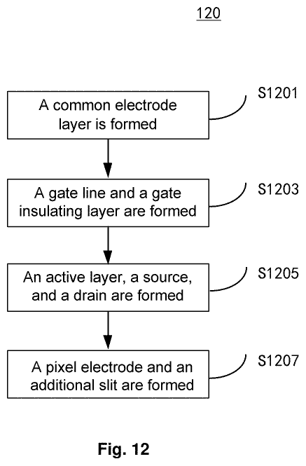

Next, the manufacturing method of an array substrate according to an embodiment of the present disclosure will be described in detail with reference to FIGS. 11 and 12. FIG. 11 illustrates a schematic flowchart of a manufacturing method of an array substrate according to the first embodiment of the present disclosure. As shown in FIG. 11, the manufacturing method 110 of an array substrate according to the first embodiment of the present disclosure may comprise the following steps.

In step 1101, a common electrode layer is formed, for example, on an array side of the array substrate. For example, the common electrode layer may be formed by process steps such as deposition or sputtering, masking, wet etching, etc. The common electrode layer may generally be formed using a transparent conductive material (for example, Indium Tin Oxide (ITO), graphene, etc.) The common electrode layer may have a sheet structure.

In step 1103, a gate line and an additional signal line are formed. For example, the gate line and the additional signal line may be formed by process steps such as deposition or sputtering, masking, wet etching etc. The gate line and the additional signal line may generally be formed using a metal material (for example, copper, aluminum, etc.) The additional signal line may be formed to be substantially parallel to an extension direction of the gate line, and a distance between the additional signal line and the gate line is equal to or greater than 5 μm. The additional signal line may be formed to have a length equal to or greater than a length of the gate line. A gate insulating layer may further be formed. For example, the gate insulating layer may be formed by a process such as deposition (for example, Plasma Enhanced Chemical Vapor Deposition (PECVD)) etc. The gate insulating layer may have a thickness of, for example, about 500 nm. The gate insulating layer may generally be formed using a material such as silicon nitride (for example, SiNx).

In step 1105, an active layer, a source, and a drain of the thin film transistor are formed. For example, the source and the drain of the thin film transistor may be formed by process steps such as deposition or sputtering, masking (for example, halftone masking), etching etc., to manufacture the thin film transistor. The active layer, the source, and the drain may be formed using a semiconductor material such as amorphous silicon, oxide, Low Temperature Poly Silicon (LTPS) etc. A data line may further be formed using a metal material such as copper or aluminum.

In step 1107, a pixel electrode is formed. For example, the pixel electrode may be formed by process steps such as deposition or sputtering, masking, wet etching, etc. The pixel electrode may generally be formed by using a transparent conductive material (for example, ITO, graphene, etc.), and the pixel electrode may be connected to the source or the drain of the thin film transistor. The pixel electrode may be formed to have a strip shape.

For example, the additional signal line may be formed to have an overlapped region with the source, and a length of the overlapped region in an extension direction of the source is in a range of 18 μm to 25 μm.

FIG. 12 illustrates a schematic flowchart of a manufacturing method of an array substrate according to the second embodiment of the present disclosure. As shown in FIG. 12, the manufacturing method 120 of an array substrate according to the second embodiment of the present disclosure may comprise the following steps. It can be understood by those skilled in the art that, for brevity, technical contents which are the same as or similar to those of the first embodiment will not be described again.

In step 1201, a common electrode layer is formed, for example, on an array side of the array substrate. For example, the common electrode layer may be formed by process steps such as deposition or sputtering, masking, wet etching, etc. The common electrode layer may generally be formed using a transparent conductive material (for example, ITO or graphene). The common electrode layer may have a sheet structure.

In step 1203, a gate line and a gate insulating layer are formed. For example, the gate line may be formed by process steps such as deposition or sputtering, masking, wet etching etc. The gate line may generally be formed using a metal material (for example, copper, aluminum, etc.) A common electrode line may further be formed at the same time. A gate insulating layer may further be formed. For example, the gate insulating layer may be formed by a process such as deposition (for example, PECVD) etc. The gate insulating layer may have a thickness of, for example, about 500 nm. The gate insulating layer may generally be formed using a material such as silicon nitride (for example, SiNx).

In step 1205, an active layer, a source, and a drain of the thin film transistor are formed. For example, the source and the drain of the thin film transistor may be formed by process steps, such as deposition or sputtering, masking (for example, halftone masking), etching etc. to manufacture the thin film transistor. The active layer, the source, and the drain may be formed using a semiconductor material such as amorphous silicon, oxide, LTPS etc. A data line may further be formed using a metal material such as copper or aluminum etc.

In step 1207, a pixel electrode and an additional signal line are formed. For example, the pixel electrode and the additional signal line may be formed by process steps such as deposition or sputtering, masking, wet etching etc. The pixel electrode and the additional signal line may generally be formed using a transparent conductive material (for example, ITO or graphene) The additional signal line may be formed to be substantially parallel to an extension direction of the gate line. The additional signal line may be formed to have a length equal to or greater than a length of the gate line and be spaced apart from the pixel electrode.

For example, the additional signal line may be formed to have an overlapped region with the source, and a length of the overlapped region in the extension direction of the source is in a range of 18 μm to 25 μm.

The embodiments of the present disclosure further provide a display apparatus including the array substrate according to the embodiment of the present disclosure as described above. The display apparatus may be any product or component having a display function such as an electronic paper, a mobile phone, a tablet computer, a television, a display, a notebook computer, a digital photo frame, a navigator, etc.

According to the embodiments of the present disclosure, the additional signal line is provided so that the additional signal line has an overlapped region with the source in the orthogonal projection direction, so as to form an additional capacitance Cₐₛ between the additional signal line and the source. The voltage on the additional signal line is set so that when the voltage applied to the gate line suddenly changes, the voltage applied to the additional signal line changes in an opposite direction. This sudden change in the voltage on the additional signal line may be coupled to the source by the capacitance Cₐₛ, thereby compensating for the jump voltage ΔVₚ caused by the sudden change in the voltage on the gate line.

Although the present disclosure has been specifically shown and described with reference to exemplary embodiments thereof, it should be understood by those of ordinary skill in the art that various changes can be made to these embodiments in form and detail without departing from the spirit and scope of the present disclosure as defined by the appended claims.

1. An array substrate comprising a plurality of pixel units, each of which comprises a thin film transistor and a pixel electrode, wherein the thin film transistor comprises a gate line, a source connected to the pixel electrode, and a drain, wherein the gate line has a first overlapped region with the source in an orthogonal projection direction perpendicular to the array substrate, and
each pixel unit further comprises an additional signal line provided to have a second overlapped region with the source in the orthogonal projection direction.

2. The array substrate according to claim 1, wherein the additional signal line is substantially parallel to an extension direction of the gate line.

3. The array substrate according to claim 1, wherein the first overlapped region has an area equal to an area of the second overlapped region.

4. The array substrate according to claim 1, wherein a length of the second overlapped region in an extension direction of the source is in a range of 18 μm to 25 μm.

5. The array substrate according to claim 1, wherein the additional signal line is provided in the same layer as the gate line.

6. The array substrate according to claim 1, wherein the additional signal line is provided in the same layer as the pixel electrode.

7. A display apparatus comprising the array substrate according to claim 1.

8. A driving method of the array substrate according to claim 1, comprising:
changing a voltage applied to the additional signal line from a third voltage to a fourth voltage when a voltage applied to the gate line is changed from a first voltage to a second voltage, wherein a difference between the first voltage and the second voltage is opposite in sign to a difference between the third voltage and the forth voltage.

9. The driving method according to claim 8, wherein an absolute value of the difference between the first voltage and the second voltage is equal to an absolute value of the difference between the third voltage and the fourth voltage.

10. A manufacturing method of an array substrate, comprising:
forming a common electrode layer;
forming a gate line and a gate insulation layer;
forming an active layer, a source, and a drain; and
forming a pixel electrode, wherein
the manufacturing method further comprises:
forming an additional signal line, wherein the additional signal line is formed as having an overlapped region with the source.

11. The manufacturing method according to claim 10, wherein the additional signal line is formed to be located in the same layer as the gate line.

12. The manufacturing method according to claim 10, wherein the additional signal line is formed to be located in the same layer as the pixel electrode.

13. The manufacturing method according to claim 10, wherein the additional signal line is formed to be substantially parallel to an extension direction of the gate line.

14. The manufacturing method according to claim 10, wherein a length of the overlapped region in an extension direction of the source is in a range of 18 μm to 25 μm.

15. The array substrate according to claim 2, wherein a distance between the additional signal line and the gate line is equal to or greater than 5 μm.

16. The array substrate according to claim 1, wherein a length of the second overlapped region in an extension direction of the source is greater than a width of the additional signal line.

17. A display apparatus, comprising the array substrate according to claim 2.

18. A driving method of the array substrate according to claim 2, comprising:
changing a voltage applied to the additional signal line from a third voltage to a fourth voltage when a voltage applied to the gate line is changed from a first voltage to a second voltage, wherein a difference between the first voltage and the second voltage is opposite in sign to a difference between the third voltage and the fourth voltage.

19. The manufacturing method according to claim 13, wherein a distance between the additional signal line and the gate line is equal to or greater than 5 μm.

20. The manufacturing method according to claim 10, wherein a length of the overlapped region in an extension direction of the source is greater than a width of the additional signal line.
